(19) United States
(12) Patent Application Publication
(10) Pub. No.: US 2004/0060659 A1
(43) Pub. Date: Apr. 1, 2004

(54) Etching system and etching method

(76) Inventors: Natsuyo Morioka, Tokyo (JP); Kenji Tamaki, Yokohama (JP); Akira Kagoshima, Kudamatsu (JP); Daisuke Shiraishi, Kudamatsu (JP); Motohiko Yoshigai, Hikari (JP); Junichi Tanaka, Tsuchiura (JP); Shoji Ikuhara, Hikari (JP); Hideyuki Yamamoto, Kudamatsu (JP)

Correspondence Address: ANTONELLI, TERRY, STOUT & KRAUS, LLP, 1300 NORTH SEVENTEENTH STREET, SUITE 1800, ARLINGTON, VA, 22209-9889, US

(21) Appl. No.: 10/413,141

(22) Filed: Apr. 15, 2003

(30) Foreign Application Priority Data
Sep. 27, 2002 (JP) 2002-282164

(51) Int. Cl. H01L 21/306

(52) U.S. Cl. 156/345.26

(57) ABSTRACT

An etching apparatus has a sensor for monitoring the etching state, an etching result estimation model for estimating an etching result from an output of the sensor and an etching result estimator, and an etching recipe calculation model for calculating a recipe based on the estimation result, in such a manner as to achieve a target etching result. In the etching method employed, when subjecting a semiconductor substrate prepared by using polysilicon to etching, calculating at least one of an oxygen gas flow rate and a pressure or both, which are included in the recipe, is calculated based on a recipe calculation model and the etching is performed using the thus-obtained parameter(s). The etching apparatus and the etching method enable desired pattern dimensions to be achieved, while suppressing variation in the final pattern dimensions.

### BACKGROUND OF THE INVENTION

The present invention relates to plasma processing technology and, more particularly, to an etching techniques for use in a semiconductor manufacturing process.

Typically, a semiconductor integrated circuit chip is manufactured by depositing a conductive layer and an insulation layer or other thin film layers sequentially on a semiconductor device wafer; forming a patterned layer using a photolithography process and an etching process for each of the layers, as required, to obtain the chips; and then separating the chips by dicing. The speed of performance of semiconductor integrated circuits, which are made from the same materials, depends mainly upon the line width of its circuit pattern, and, therefore, the microfabrication of circuit patterns has been developed in recent years. A dry etching process has been developed as one of the etching techniques used for the microfabrication of a circuit pattern.

In one example of a dry etching process, etching gases are introduced into a vacuum chamber so as to generate a plasma discharge under a reduced pressure, and radicals or ions generated in the plasma are made to react with a wafer surface, which is the subject of the etching. In this case, the etching is performed based on setting conditions which are called a “recipe”. Parameters defined in the recipe include the gas flow rate, the gas pressure, the inputted power, the etching time, and so forth. Conventionally, one recipe has been used for one etching process.

In dry etching, a reactant film, which is generated from the reaction between the wafer and the etching gases, tends to build up on the reactor walls due to the mechanism of the etching. Thus, an unnecessary gas called an “outgas” is generated from the reactant film, so that the conditions within the reactor tend to drift. The conditions within the reactor can also drift due to temperature changes of the reactor-associated parts and deterioration of other parts. Thus, there are various disturbance factors which influence the etching result in the dry etching process.

Further, a variation in the dimensions of the shapes of masks formed by a lithography process, which is a pretreatment performed in advance of the etching, significantly influences the etching result. That is to say, even if etching is performed by the use of a constant recipe, it is difficult to achieve a constant performance due to various disturbance factors.

As a related technique for compensating for the various disturbance factors, a method of controlling the amount of etching by finely controlling the etching time, among the parameters of the recipe depending on the state of the apparatus, has been reported by Thomas F., Edgar S., Joe Qin, W. J. Campbell, Short Course, “Run-to-Run Control and Fault Detection”, AEC/APC Symposium XII, September 2000, pp. 110-115.

Although no specific example of the control method is disclosed in the above-referenced literature, the etching is usually performed based on certain conditions, the result is measured after the completion of the etching, and the etching time is finely controlled, based on the result, to perform a subsequent process. In this case, the measurement of the etching result is performed on an off-line basis, by using a scanning electron microscope (SEM) or the like, after processing a lot (several to 25 sheets) of the wafers. Therefore, there has been a problem in that there is a delay of 1 to 2 lots before the actual application of the fine-control to the etching.

Further, in the case where the etching amount is controlled by finely controlling the etching time, the deviation in the final pattern dimensions in one lot, or between lots, is sometimes increased.

### SUMMARY OF THE INVENTION

The object of the present invention is to solve the above-mentioned problems.

The invention is directed to the etching of a semiconductor substrate prepared by using polysilicon and is characterized by controlling the amount of etching by changing at least one of the oxygen gas flow rate and the pressure, or both, which are used as parameters for controlling the etching.

More specifically, the invention is characterized by calculating at least one of the oxygen gas flow rate and the pressure, or both, which are used as parameters in a parameter calculation system for controlling the etching so as to achieve a target etching amount of an etching apparatus, based on an estimated result of the etching, so that subsequent etching is controlled based on the calculation result of the parameter calculation system.

### BRIEF DESCRIPTION OF THE DRAWINGS

FIG. 1 is a block diagram schematically showing an etching apparatus;

FIG. 2 is a diagram showing an outline of an etching process according to a first embodiment of the present invention;

FIG. 3 is a flowchart showing the etching process according to the first embodiment of the present invention;

FIGS. 4A to 4D are diagrams showing CD bias amounts;

FIG. 5 is a flowchart showing a process for determining control factors;

FIGS. 6A and 6B are graphs showing results of experiments;

FIG. 7 is a diagram showing a relationship between the control factors and the CD bias amount;

FIG. 8 is a diagram showing an outline of the etching process according to the first embodiment of the present invention;

FIGS. 9A and 9B are diagrams showing a parameter value calculation model;

FIGS. 10A and 10B are diagrams showing a method of adjusting the parameter value calculation model;

FIGS. 11A and 11B are diagrams showing a method of estimating an etching result;

FIGS. 12A to 12C are diagrams showing an effect of the first embodiment of the present invention;

FIG. 13 is a flowchart showing an etching process according to a second embodiment of the present invention; and

FIG. 14 is a diagram showing an etching process according to a third embodiment of the present invention.

### DESCRIPTION OF THE PREFERRED EMBODIMENTS

Various embodiments of the present invention will be described with reference to the accompanying drawings.

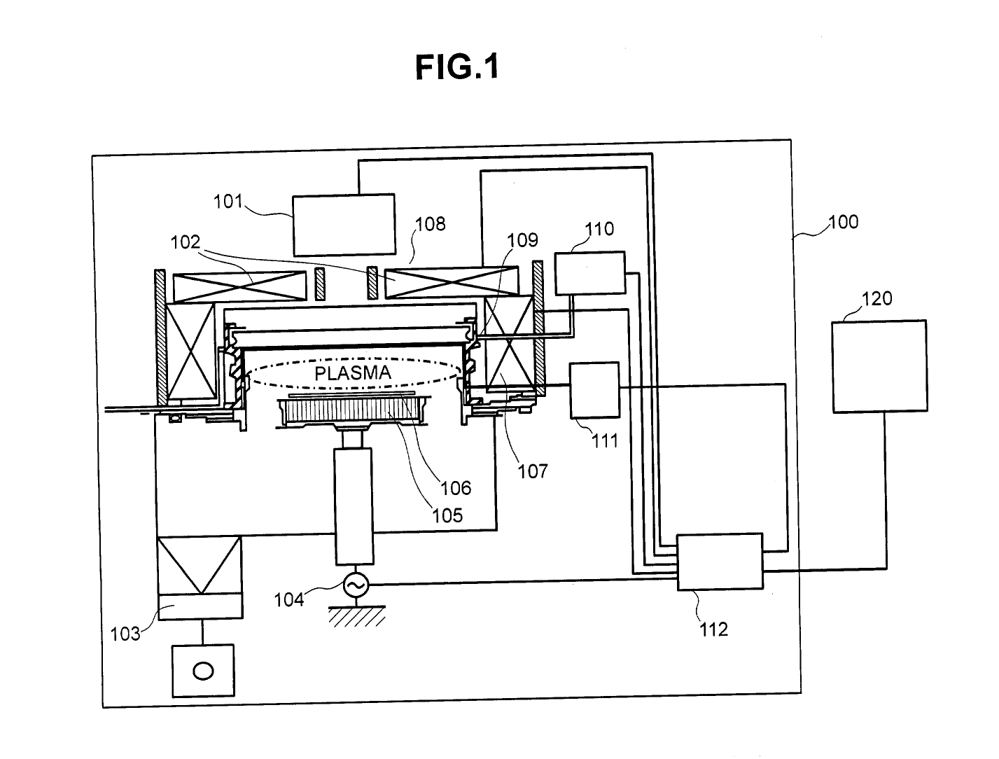

First of all, an outline of a dry etching apparatus, to which the present invention is applied, will be described. FIG. 1 is a block diagram showing the dry etching apparatus.

FIG. 1 shows an example of the dry etching apparatus, which includes a body 100 and a measurement tool 120 connected to the body 100. The measurement tool 120 may be provided either externally, as in the illustrated example, or inside the body 100 in an incorporated fashion. The body 100 is also provided with a control unit 112, which controls the operation of the etching apparatus in response to outputs from the measurement tool 120. A CD-SEM for measuring a pattern width, after completion of the etching operation, is typically used as the measurement tool 120, and, in the alternative, an optical critical dimension measurement tool called a “scatterometry” apparatus, which utilizes scattered light, may be used as the measurement tool 120.

An etching reactor 109, a gas delivery system 110 for delivering a process gas to the etching reactor 109, and a gas exhaust device 103 for exhausting the process gas and for controlling the pressure (chanber pressure) inside the etching reactor are provided inside the body 100. A stage 105 for supporting a substrate 106, which is the subject of the etching, is mounted inside the etching reactor 109. The etching reactor 109 is further provided with a plasma generating device 108 for generating a plasma.

The plasma generating device 108 is provided with an electromagnetic wave supplying unit 101 for supplying electromagnetic waves to the reaction space of the etching reactor 109, and solenoid coils 102 and 107 are provided for generating a magnetic field inside the etching reactor 109. A RF biasing voltage is applied from a RF power supply 104 to the stage 105 so as to accelerate the generated plasma (ions) toward the substrate 106.

The dry etching apparatus is provided also with an apparatus monitoring device 111. The apparatus monitoring device 111 includes a monitor for detecting the flow rate of gas delivered from the gas delivery system 110, a detector for detecting the current and voltage of a feed line for supplying power for the plasma generation, a detector for detecting the phase difference for the current and the voltage, a detector for detecting a progressive wave and a reflected wave of the RF power supplied for the plasma generation, an impedance monitor, and so forth.

The apparatus monitoring device 111 monitors the amount of processing that occurs in the etching process for the flow rate and the pressure of the gas delivered to the apparatus, the power supplied to the apparatus, and so forth, and it includes an analyzer for detecting and analyzing emissions from the plasma generated by the plasma generating system 108. It is desirable that the analyzer provided in the apparatus monitoring device 111 be a detector, such as an optical emission spectroscope, which can output multiple signals; however, a detector, such as a monochromator, which takes out light of single wavelength, also may be used as the analyzer. The emission spectrum output by the spectroscope is a signal representing the optical intensity of each of the wavelengths. Alternatively, the apparatus monitoring device 111 may be an ordinary plasma monitor, such as a quadrupole mass spectrometer, which outputs mass spectrums of molecules in the plasma. The additional sensor embodied in the apparatus monitoring device 111 for monitoring the values during the etching will be referred to as an “In-Situ sensor” in the following description. In order to perform etching while monitoring the state thereof and providing feedback to the apparatus, the recipe is changeable during wafer processing or for every wafer to be processed.

The control unit 112 has a function of controlling the operation of the apparatus in response to outputs received from the apparatus monitoring device 111. For example, the control unit 112 performs supply and cut-off of the power supplied to the plasma generating system 108, which is provided with a magnetron for producing the electromagnetic waves and the magnetic field to be used for generating the plasma, or it performs adjustments of the inputted power. Alternatively, it is possible to adjust the plasma output by the use of another device. For example, the apparatus monitoring device 111 may detect certain reaction states, such as an increase and a decrease of a specific reactant associated with the etching, a reaction rate, and the plasma density based on detection data of light of a predetermined wavelength which is generated during the etching process using the plasma, and it may instruct generation and suspension of the plasma as well as start-up and stopping of the apparatus, so as to control the operation of the etching apparatus.

An outline of the etching process, in accordance with the present embodiment, will be described below.

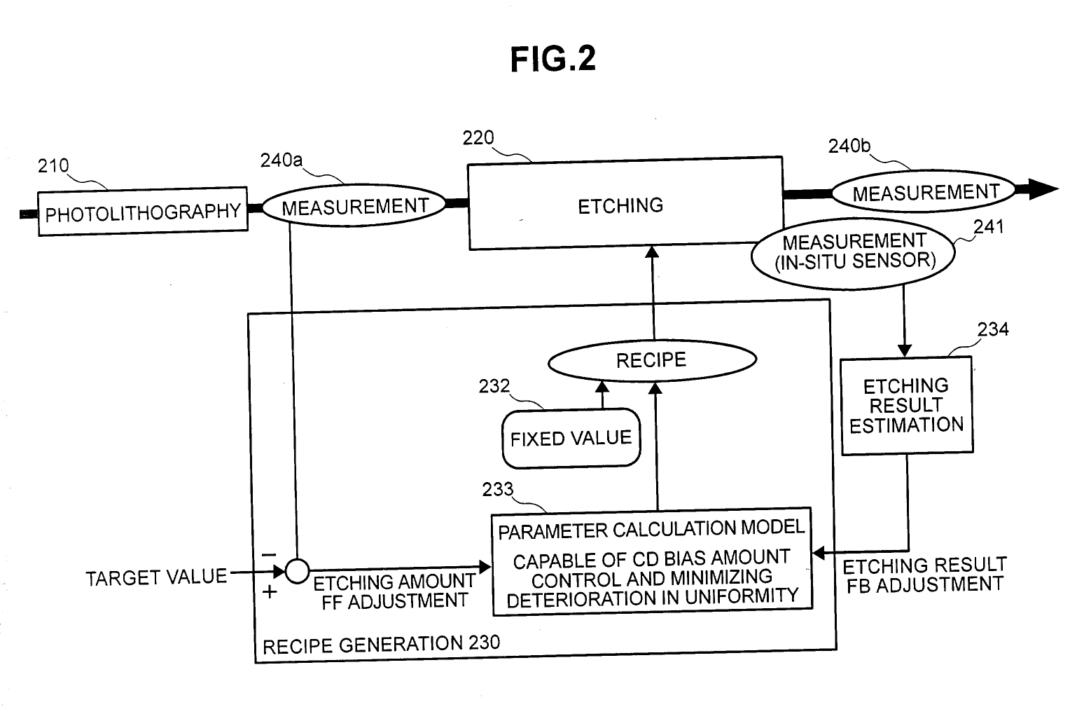

FIG. 2 is a diagram showing an outline of the etching process of the present embodiment.

In a gate patterning process during manufacture of a semiconductor device, a photolithography step 210 is performed in advance of an etching step 220. In the photolithography step 210, a resist is applied on a gate electrode material, which is deposited on a semiconductor substrate to be developed. Then, the resist is subjected to etching treatment in the etching step 220 so that a gate electrode having a target gate length is obtained on a gate portion of a target field effect transistor. The etching results of the photolithography step 210 and the etching step 220 are measured, as required, in the steps 240a and 240b by measuring the gate lengths using the measurement tool.

The gate lengths are referred to as “CD (critical dimension) values” in the following description. The CD values used in the present embodiment include a measurement CD value of the resist before etching, a target CD value which is a target etching amount, and a final CD value which is measured after the etching. The device used for the measurements 240a and 240b may be an inspecting apparatus, such as a CD-SEM. The apparatus of the present embodiment has a recipe generating block 230 for generating recipes which enable the result of the etching step 220 to be identical with the target gate length.

An outline of the process performed by the recipe generating block 230 will be described below.

In the recipe generating block 230, an etching amount is calculated from an inputted target value 231 for the gate length and a CD value of the resist measured by the inspecting apparatus (CD-SEM or the like) in the step 240a, and the calculated etching amount is inputted to a parameter calculation model 233 (feed-forward adjustment). Then, a recipe for achieving the target etching amount is generated.

In the present embodiment, some of the parameters included in the recipe are fixed (232) throughout the etching process, while other parameters are finely controlled for the achievement of the target etching amount. The parameters to be finely controlled are those that can contribute to the control of the etching amount and yet hardly result in variation in the etching result even if they are changed. Then, parameters which enable control of the target etching amount are calculated by the use of the parameter calculation model 233 to generate the recipe, with the thus-obtained parameters being associated with the fixed parameters. The etching apparatus performs an etching based on the recipe thus generated.

The state of the etching is monitored by the In-Situ sensor 241. A final CD value is estimated by using monitor outputs from the In-Situ sensor 241 and a predetermined etching result estimator with an etching result estimation model 234, and the parameter calculation model is adjusted (feedback adjustment) as required depending on the estimation result, in such a manner as to suit the monitored state of the apparatus. The In-Situ sensor 241 can monitor each of the wafers during the wafer processing, and it is possible to estimate an etching result for each of the wafers by the use of the etching result estimation model 234.

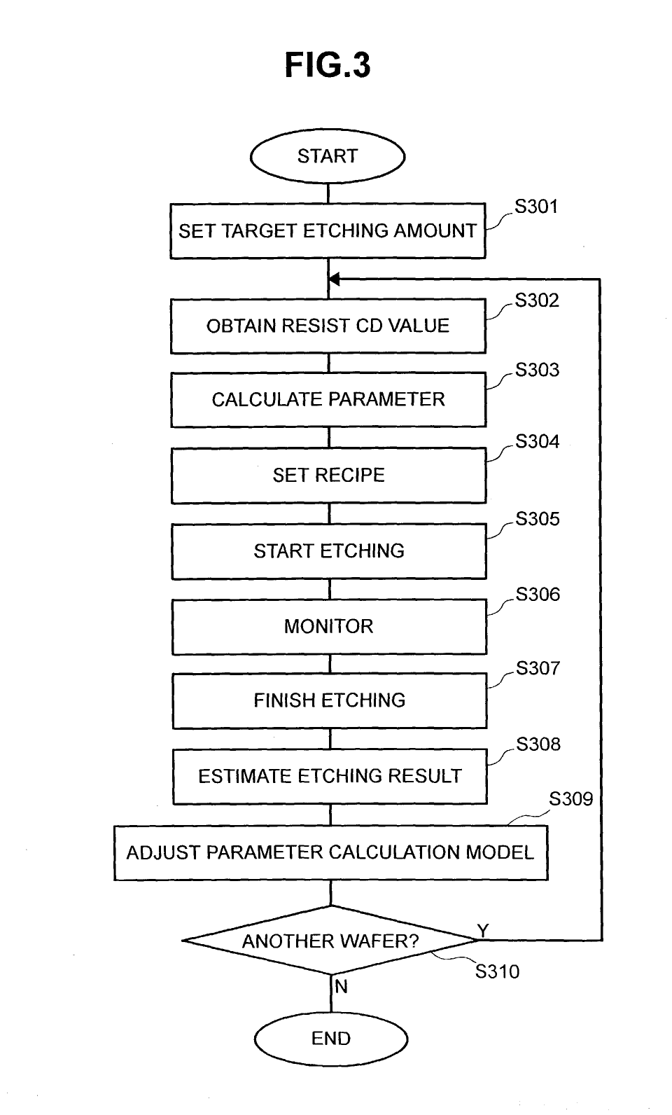

A summary of the above-described flow of the process according to the present embodiment is shown in FIG. 3.

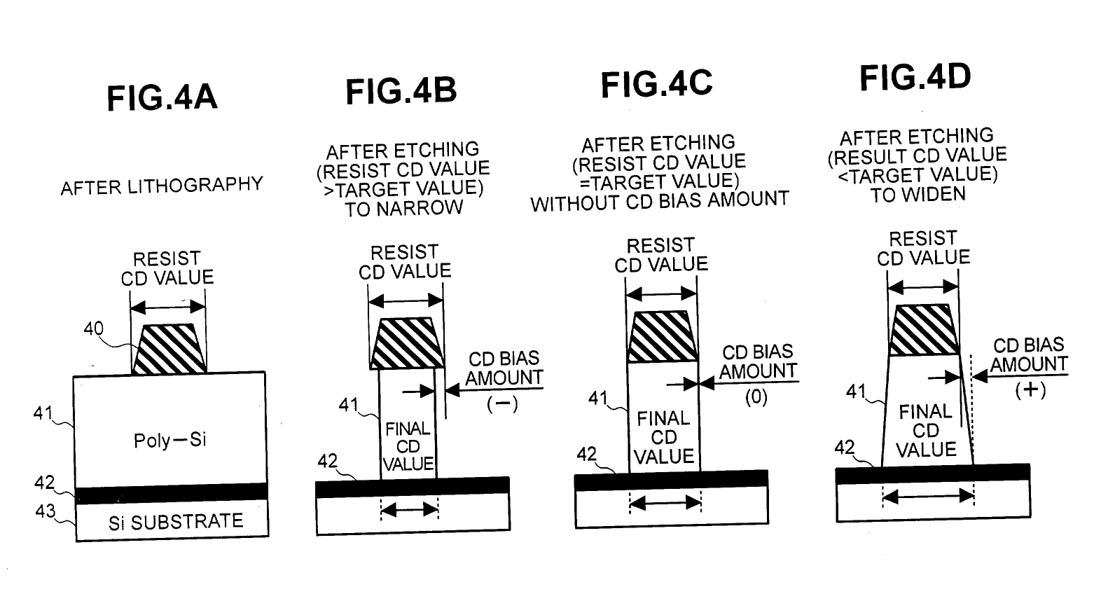

The target etching amount will be described below. FIGS. 4A to 4D are diagrams each showing a relationship between the resist CD value and the etching amount.

A part of the semiconductor substrate after the photolithography step is shown in FIG. 4A. Over the Si substrate 43, an insulator 42 and polysilicon 41 are deposited in this order, and a resist 40 is patterned on the polysilicon 41.

There are three types of final CD value-etching amount relationships, as shown in FIGS. 4B to 4D. FIG. 4B shows the case where the resist CD value is larger than the target final CD value. In this case, the etching must be performed in such a manner as to make the final CD value smaller than the resist CD value (narrowing). In the case of FIG. 4B, the CD bias amount corresponding to an etching amount for canceling the difference between the resist CD value and the final CD value is a negative value. The case where the resist CD value is equal to the final CD value is shown in FIG. 4C, wherein the CD bias amount is 0. The case where the final CD value is larger than the resist CD value is shown in FIG. 4D, wherein the CD bias amount is a positive value. In this case, the etching must be performed in such a manner as to make the final CD value larger than the resist CD value (widening).

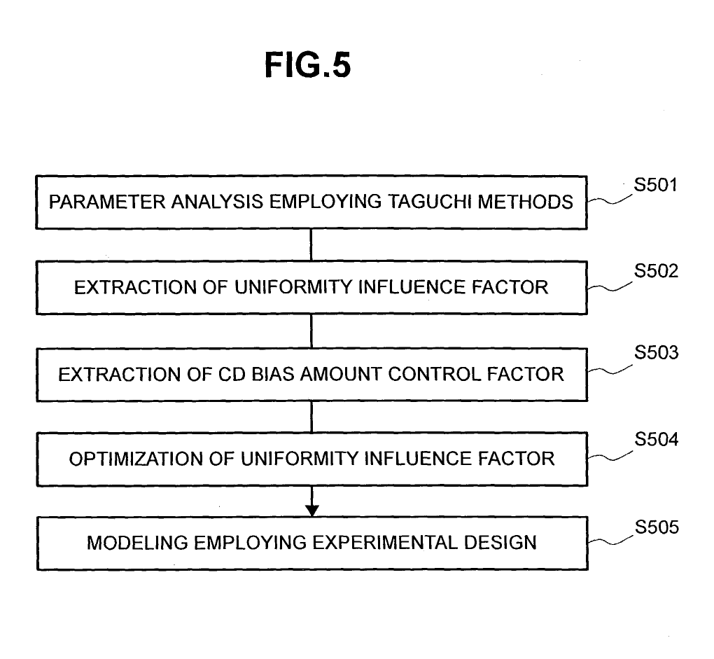

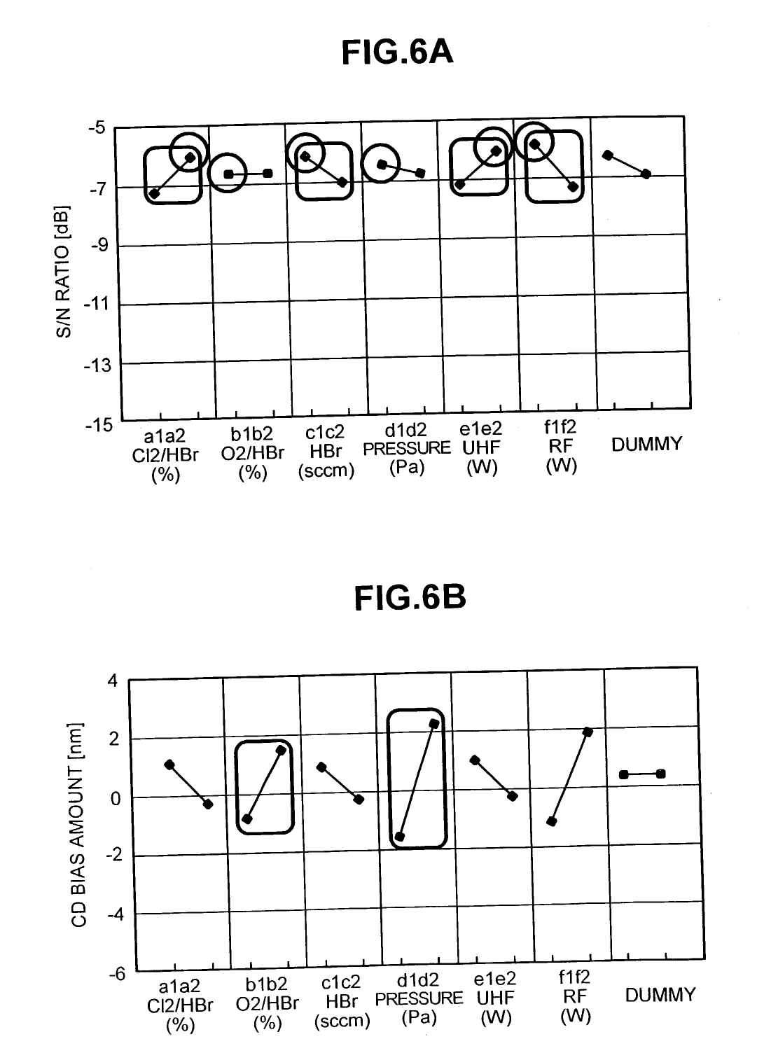

A method of determining the parameter values of the recipe for achieving the target final CD value by controlling the CD bias amount, depending on the resist CD value and the condition of the etching apparatus, will be described below with reference to FIGS. 5 to 6B.

FIG. 5 is a flowchart showing steps for determining values of the parameters of the recipe. However, before explaining the analysis of the parameters which are defined in the recipe, the functions of the parameters in the etching reaction will be described.

(1) Cl₂ gas, (2) HBr gas

Cl₂ gas and HBr gas react with polysilicon, which is the material to be subjected to etching, to form a compound for evaporating and exhausting the polysilicon in the gas phase. The unit of measurement of the HBr gas is sccm (standard cubic centimeter per minute), which indicates a volume of the gas to be supplied for one minute.

(3) O₂ gas

O₂ gas reacts with polysilicon to form a compound, which is deposited on the side walls of an etching pattern to form a layer protecting the side walls. Further, the O₂ gas reacts with hydrogen atoms that are dissociated from the HBr gas to form H₂O. H₂O is readily vaporized under a reduced pressure to be exhausted. The parameters of the Cl₂ gas flow rate and the O₂ gas flow rate are determined on the basis of the proportions of the Cl₂ gas flow rate to the HBr gas flow rate and the O₂ gas flow rate to the HBr gas flow rate. This is because the Cl₂ gas reacts with polysilicon correlatively with the HBr gas, and the O₂ gas promotes the etching reaction correlatively with the HBr gas.

(4) Pressure

An amount of gaseous molecules existing in the etching reactor is determined on the basis of the pressure. The pressure is adjusted by the use of a variable valve by exhausting the gas in an amount which is based on the flow rate of the gas delivered to the reactor.

(5) UHF Power

The UHF power is the power to be supplied to the electromagnetic wave supplying unit 101 (see FIG. 1), which contributes to the generation of plasma from the gas. The plasma density is increased with an increase in the UHF power.

(6) RF Power

The RF power is the power supplied to the stage 105 (see FIG. 1), which has an effect of attracting the ions to the substrate. The amount of ions is increased with an increase in the supplied RF power.

(7) Dummy Factor

Experiments were conducted while employing the Taguchi methods, wherein the parameters (1) to (6) are allocated on orthogonal arrays. The Taguchi methods are techniques of analyzing parameters for manufacturing conditions in a semiconductor manufacturing apparatus or the like to extract the characteristics thereof. More specifically, combinations of a plurality of parameters with different conditionings are represented on the orthogonal arrays, and experiments are conducted in accordance with the orthogonal arrays to analyze the parameters based on the results of the experiments. In the experiments, the dummy factor suggests whether or not there is a factor that tends to influence the etching result (CD bias amount), other than the selected six recipe parameters. On the orthogonal arrays, the dummy factor is assigned on the seventh array, so that the same calculation is performed for the dummy factor. If the S/N (signal to noise) ratios of the first level and the second level are different from each other to a large extent in the calculation result, such a difference indicates the existence of an important factor besides the six parameters. In the present experiments, the existence of an important factor was not confirmed.

(8) Other Parameters Which Were Not Used for the Parameter Design

Coil Current

The coil current indicates the value of a current flowing through the solenoid coil placed above and around the reactor. The magnetic field distribution in the reactor is determined by the coil current, based on which the plasma distribution is determined. The plasma distribution was not used for the parameter design for selecting the control factor, since it significantly influences an in-plane variation in the etching result.

Temperature

The temperature of the stage influences each of the reactions which are decisive in determining etching reaction velocity, such as the adsorption of the ions on polysilicon, the reaction between the ions and polysilicon, and the evaporation of the ions from polysilicon. Since a relatively long time is required for the temperature to be saturated, it is difficult to dynamically control the temperature. Accordingly, the temperature was excluded from the control factors.

Etching Time

The etching time is also a factor that influences significantly influences the etching result. However, the etching time was excluded from the control factors, since termination of the etching is usually based on end point detection.

The method of analyzing the parameters will be described below with reference to FIG. 5. FIG. 6A and 6B are graphs showing the results of experiments.

The parameter analysis of an etching apparatus was conducted employing the Taguchi methods (S501). The Taguchi methods are, as described above, techniques used in analyzing parameters for manufacturing conditions in a semiconductor manufacturing apparatus or the like to extract the characteristics thereof. More specifically, combinations of a plurality of parameters with different conditionings are represented on the orthogonal arrays, and experiments were conducted in accordance with the orthogonal arrays to analyze the parameters based on results of the experiments.

Parameters having a relatively great influence on a deviation (uniformity) in the etching result are extracted, based on the experimental results (extraction of uniformity influence factor in S502 of FIG. 5).

A position on a wafer, a pattern density difference, and a material difference are considered to be factors which tend to cause an error in the CD value, which corresponds to a variation in the etching result. In order to accurately detect such an error, the CD bias amounts of patterns which are different in error factor were measured and used to calculate a S/N ratio and a uniformity.

The S/N ratio is a relative index for determining the degree of variation, and it is obtained as a result of dividing the square of the average value of the CD bias amounts by the square of the variance and then taking the logarithm of the quotient. Since the S/N ratio is a relative unit, it does not represent an absolute value, although it enables comparison among values of a parameter.

In turn, the uniformity represents the absolute value of the variation. The value of the uniformity is obtained by dividing the difference between a maximum CD bias amount and a minimum CD bias amount by a sum of the maximum and minimum CD bias amounts. The S/N value, which is a relative unit, is usable for effecting a comparison among values of a parameter, and it is necessary to use the uniformity, which is obtained by dividing a difference between the maximum CD bias amount and the minimum CD bias amount by a sum of the maximum and minimum CD bias amounts, for the detection of the absolute value of each of the variations under the recipes.

FIG. 6A is a graph showing a relationship between the parameters and the uniformity. As shown in FIG. 6A, the S/N ratio, which is the index for the uniformity, of each of the Cl₂ gas/HBr gas flow rate ratio, HBr gas, the UHF power, and the RF power changes when the parameters are changed from a1, c1, e1, and f1 to a2, c2, e2, and f2, respectively, Therefore, these parameters are considered to be in-plane uniformity influence factors which have considerable influences on the uniformity in the CD bias amount. In turn, the O₂ gas/HBr gas flow rate ratio and the pressure hardly influence the uniformity even when the parameters are changed from b1 and d1 to b2 and d2, respectively. Since the parameters to be used for controlling the CD bias amounts have a desirably low influence on the uniformity, those which are relatively high in influence on the uniformity are excluded from the control factors.

Then, parameters which are superior in controlling the CD bias amounts are extracted from the parameters having a slight influence on the uniformity (extraction of CD bias amounts control factor in S503).

FIG. 6B is a graph showing the relationships between the parameters and the CD bias amount. The parameters which are superior in controlling CD bias amounts are the pressure, the RF power, and the O₂ gas/HBr gas flow rate ratio. However, since the RF power behaves also as a uniformity influence factor, the pressure and the O₂ gas/HBr gas flow rate ratio are extracted as parameters that are considered to be superior in controlling the CD bias amounts.

The parameters which are high in influence on the uniformity are optimized in such a manner as to minimize then influence, so that the parameters are fixed to the optimized values (optimization of uniformity influence factor in S504). The parameters which are low in influence on the uniformity and superior in controlling CD bias amounts (the O₂ gas flow rate and the pressure in the present embodiment), which have been detected in Step S503, are subjected to experiments for detecting the relationships between changes in the parameters and the CD bias amounts in order to derive a model (S505).

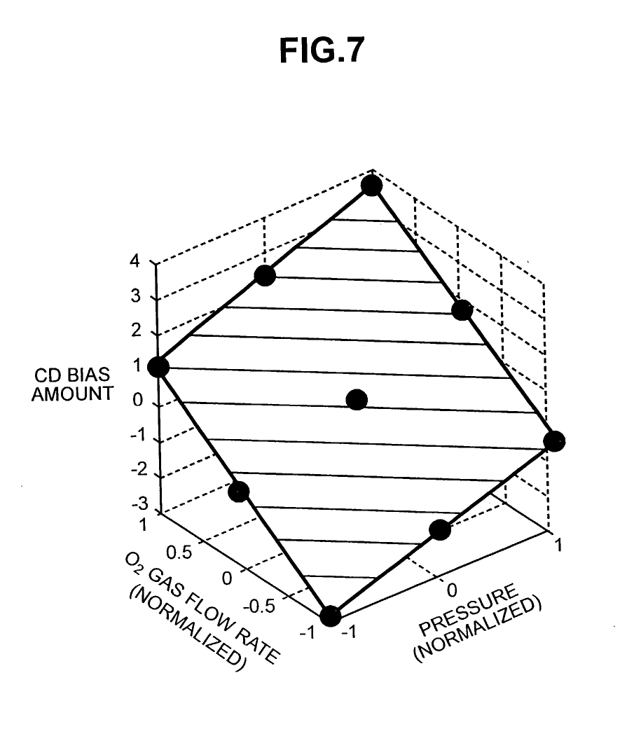

FIG. 7 is a diagram showing a relationship among the pressure, the O₂ gas flow rate, and the CD bias amount. This is a model for the recipe calculation.

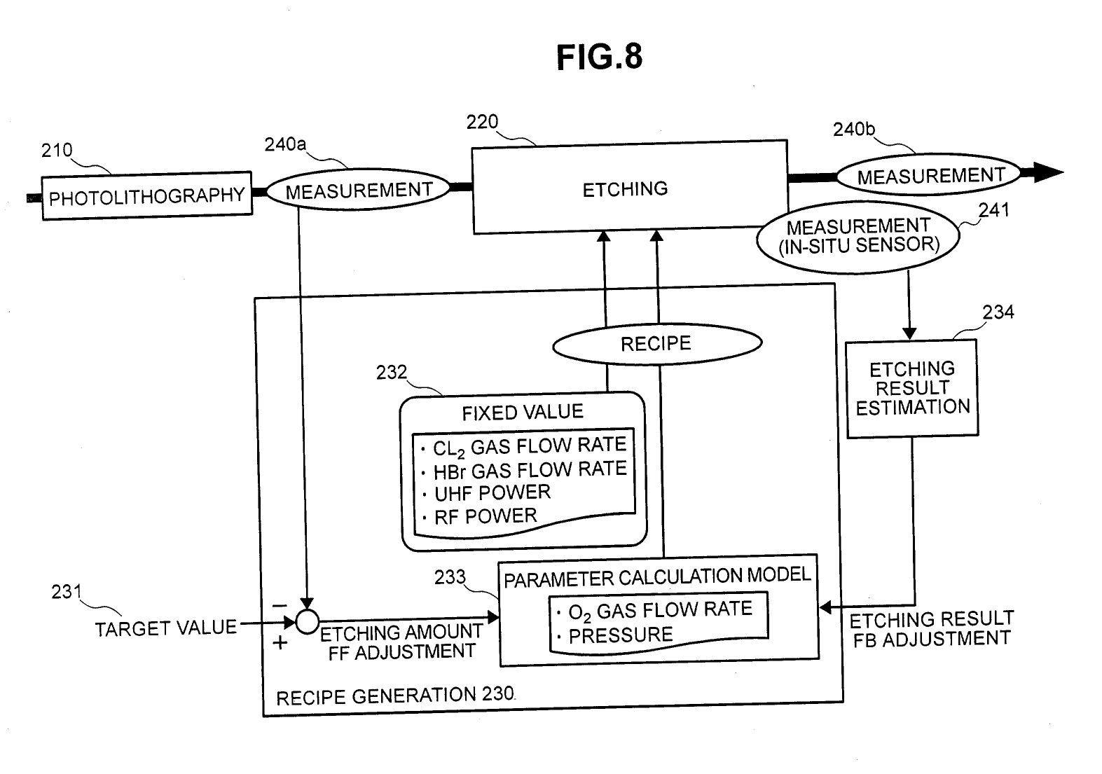

FIG. 8 is a diagram showing an outline of the process for controlling etching, wherein the recipe is generated by using the pressure and the O₂ gas flow rate as the CD bias amount control factors and the other parameters as fixed parameters.

FIG. 8 shows the outline of an etching process that is similar to that of FIG. 2; and, in FIG. 8, specific parameters are additionally indicated as fixed values 232 and the parameter calculation model 233. In the process of FIG. 8, to generate a recipe used for providing manufacturing conditions to achieve a target etching amount, the C1₂ gas/HBr gas flow rate ratio, the HBr gas, the UHF power, and the RF power are fixed throughout the etching process, while the pressure and the O₂ gas/HBr gas flow rate ratio are adjusted so as to achieve the target etching amount. Values of the pressure and the O₂ gas/HBr gas flow rate ratio, which enable achievement of the target etching amount, are determined by calculations using the parameter calculation model 233.

The calculations of parameters using the parameter calculation model will be described below.

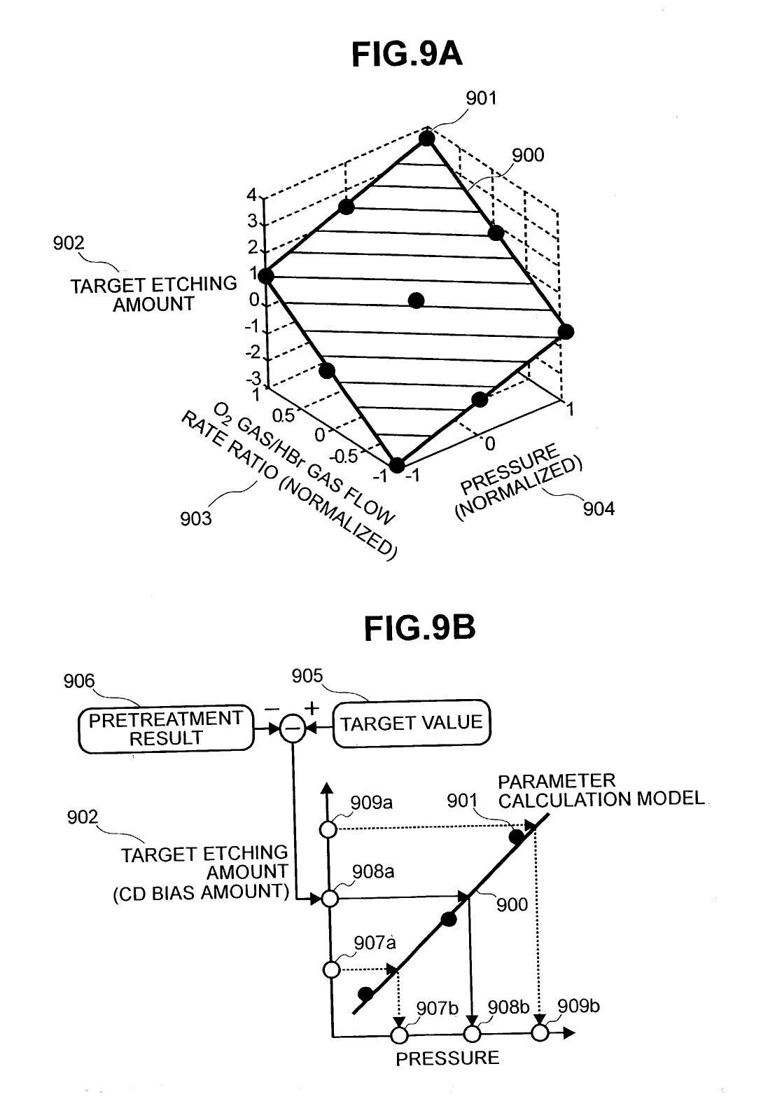

FIGS. 9A and 9B are diagrams showing an example of the parameter calculation model according to the present embodiment. FIG. 9A shows a model representing a relationship between the two parameters of pressure and the O₂ gas/HBr gas flow rate ratio, and the target etching amount. In FIG. 9A, the target etching amount (equivalent to the CD bias amounts of FIGS. 4B to 4D) is represented on axis 902; the O₂ gas/HBr gas flow rate ratio which is one of the control factors, is represented on axis 903; and the pressure, which is the other control factor, is represented on axis 904. A recipe calculation model 900 is represented by an RSM (Response Surface Model) curve, and dots 901 indicate experimental values.

FIG. 9B shows a simplified version of the graph of FIG. 9A, showing a relationship between the pressure, which is one of the control factors, and the target etching amount. In FIG. 9B, reference numeral 900 denotes a linear response curve, which is represented as a regression line for the purpose of simplification. Three experimental values are shown in FIG. 9B. The model is used for the reserve calculation (calculation backward) of a parameter based on a target etching amount. The target etching amount 902 of FIG. 9B corresponds to the CD bias amount of FIGS. 4B to 4D, which is obtained by subtracting a pretreatment result 906, which is a resist CD value, from a target value 905, which is the target value of the final CD value. Therefore, even if the pretreatment result 906 changes, it is possible to achieve the target value by changing the etching conditions in accordance with the change.

If the pretreatment result 906 is equal to the target value 905 (corresponding to FIG. 4C), a parameter 908b for the achievement of a target etching amount 908a is retrocalculated by the use of the model 900, and then the etching result shown in FIG. 4C is achieved by performing an etching using the thus-obtained parameter.

If the pretreatment result 906 is larger than the target value 905 (corresponding to FIG. 4B), a parameter 907b is retrocalculated from a target etching amount 907a, and then the etching result shown in FIG. 4B is achieved by performing an etching using the thus-obtained parameter.

If the pretreatment result 906 is smaller than the target value 905 (corresponding to FIG. 4D), a parameter 909b is retrocalculated from a target etching amount 909a, and then the etching result shown in FIG. 4D is achieved by performing an etching using the thus-obtained parameter.

The above-described retrocalculations are performed on a simplified two-dimensional graph. To control the CD bias amount by controlling two factors, a combination of values of two factors which contribute to the achievement of the target CD bias amount may be selected on the RSM 900 of FIG. 9A. In this case, it is possible to obtain the recipe either by mainly adjusting one of the factors or by adjusting both of the factors respectively with a relatively small unit.

The parameters to be calculated by the use of the parameter calculation model shown in FIG. 9A are the O₂ gas flow rate and the pressure. Other parameters (Cl₂ gas flow rate, HBr gas flow rate. UHF power, RF power, etc.) are treated as fixed parameters. Then, a recipe, in which the parameters, including the fixed parameters, are defined, is generated and then set in the etching apparatus to start an etching process 220.

A method of adjusting the parameter calculation model will be described below.

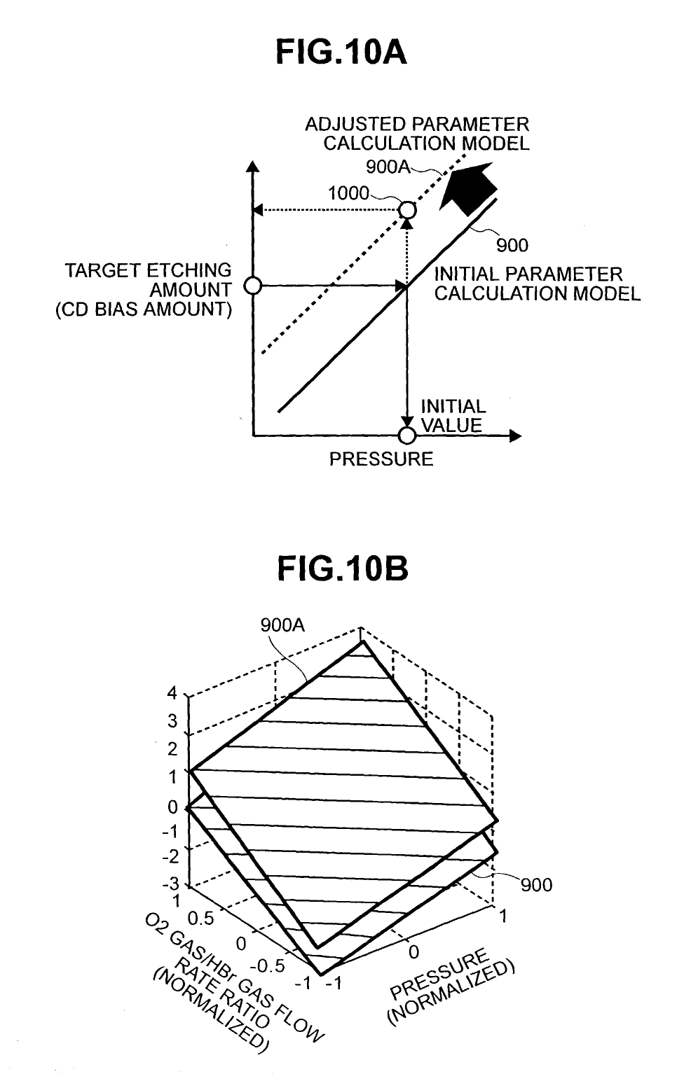

FIGS. 10A and 10B are diagrams illustrating a method of adjusting the parameter calculation model. In the case where a target etching amount is achieved as a result of an etching using the recipe generated for the target etching amount, the parameter calculation model does not need to be adjusted. However, if the desired result was not achieved, it is necessary to adjust the parameter calculation model. An adjusted parameter calculation model 900A, which is obtained by plotting an actual etching amount 1000 of an initial recipe used for an etching and advancing therealong, is used for the adjustment. In the example shown in FIG. 10A, the inclination of the model is constant while the segment is adjusted. Alternatively, the inclination may be adjusted with the segment being fixed.

A method of controlling the CD bias amount by the use of the O₂ gas flow rate and the pressure, will be described in detail below. The amount of adjustment of the CD bias amount achieved by the single use of the O₂ gas flow rate is 3 nm, while the amount of adjustment of the CD bias amount achieved by the single use of the pressure is 4 nm.

FIG. 10B shows a parameter calculation model showing a relationship between the two parameters of the O₂ gas/HBr gas flow rate ratio and the pressure and the target etching amount, wherein the segment is adjusted. As in the case of the linear regression model, the parameter calculation model is adjusted by plotting an initial recipe and an actual etching result thereof. Then, a recipe is generated by using the adjusted parameter calculation model to perform an etching on a wafer based on the thus-generated recipe. After that, etching is performed, while the parameter calculation model is being adjusted, until the completion of etching of a series of wafers (usually referred to as a lot), which have been set in the etching apparatus.

There are many combinations of the O₂ gas flow rate and the pressure usable to achieve the target bias amount, as shown in FIG. 10B. Therefore, if the target CD bias amount is 3 to 4 nm, it is possible to adjust the CD bias amount either by the use of one of the factors, with the other factor being fixed, or by finely controlling both of the factors.

To adjust the CD bias amount to a value as large as 7 rim, both of the factors must be adjusted. In order to adjust the CD bias amount by 7 rim or more, a third control factor may be used. The use of the third control factor involves a certain degree of deterioration in the uniformity. It is known that the RF power is highly effective for adjustment of the CD bias amount, and, therefore, the RF power is promising as the third control factor.

The reason why the O₂ gas flow rate and the pressure are appropriate for use as control factors is as follows.

Since the O₂ gas flow rate contributes to the thickness of the side wall protection layer, as described above, with the increase in the O₂ gas flow rate, the thickness of the protection layer deposited on the side wall is increased, and, thereby, the CD bias amount is increased. The amount of gaseous molecules depends upon the pressure in the reactor. The amount of molecules attracted to the substrate is increased with an increase in the pressure, so that the thickness of the protection layer deposited on the side wall will be increased.

The estimation of an etching result (the etching result estimation 234 of FIGS. 2 and 8) will be described below.

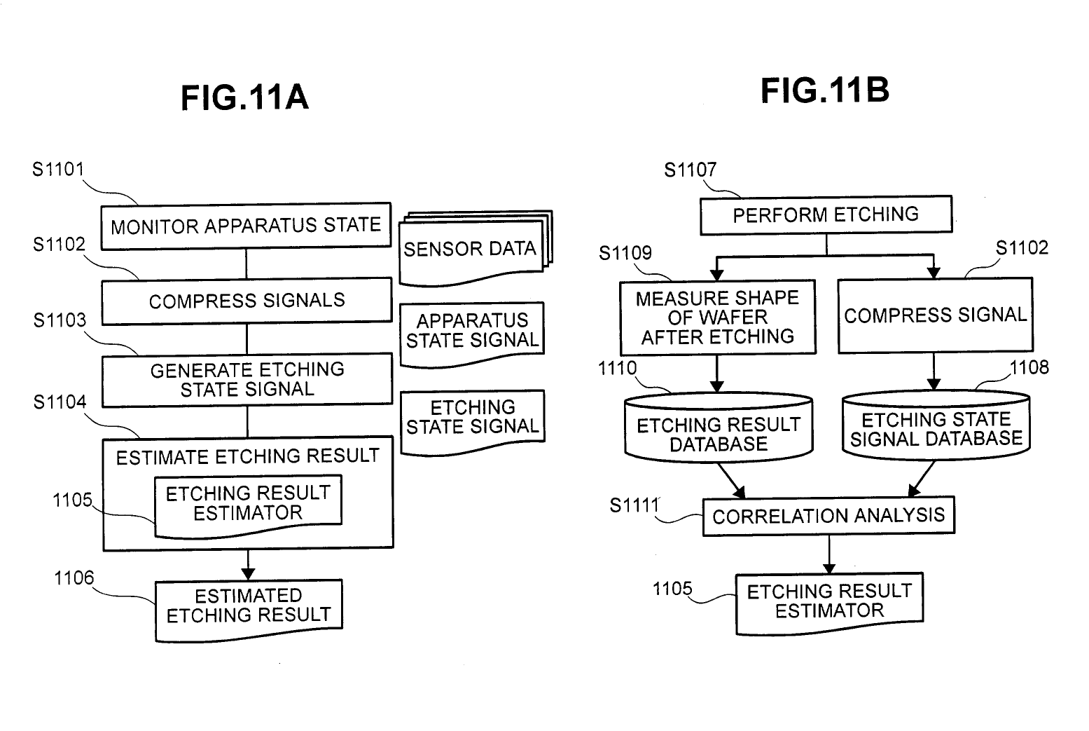

FIG. 11A is a flowchart of a process for obtaining an estimated etching result from data provided by the In-Situ sensor, which monitors the state of the apparatus.

Examples of the In-Situ sensor, which monitors the processing amount to be used for obtaining the etching result estimation, include an optical emission spectroscope that is capable of outputting a large quantity of data, a plasma impedance monitor having a high sensitivity to the state of the plasma, or other sensors for pressure, temperature, voltage, inputted power, reflected power, etc. Alternatively, an optical emission spectroscope, which can obtain various data at the same time, may solely be used as the In-Situ sensor. Signals indicating the state of the apparatus are obtained at a predetermined interval, for example, per second, by using the sensor(s) (S1101), the sensor(s) obtaining several tens to several thousands of signals at one time.

The large quantity of data obtained is compressed to generate apparatus state signals indicating the state of the apparatus (S1102). Although the number of apparatus state signals is changeable as the case may be, several to several tens of these signals are typically generated. A statistical analysis method, such as a principal component analysis, is employed for the signal compression.

An etching state signal for each of the wafers is generated by averaging or differentiating changes with time in the apparatus state signals thus obtained (S1103).

The etching shape of a wafer is estimated by the use of the etching state signal and the etching result estimator, which has been obtained beforehand (S1104). The etching result estimator 1105 has been stored in the database so as to be available for use for estimation of the etching result of the wafer. Further, in the etching result estimation (S1104), variation in the shape of the wafer after the etching is also calculated by using the etching state signal.

FIG. 11B is a flowchart showing a process for generating the etching result estimator 1105 shown in FIG. 11A. First of all, a wafer is subjected to etching using an etching apparatus (S1107). Then, data obtained by the sensor(s) for monitoring the amount of processing is compressed (S1102). The compressed data is stored in an etching state signal database (S1108). The shape of the wafer after the etching is measured by using a measurement tool, such as a CD-SEM (S1109), and the measured result is stored in an etching result database (S1110). A correlation equation of the measured shape and the etching state signal is obtained by a multiple regression analysis to generate the etching result estimator 1105 (S1111).

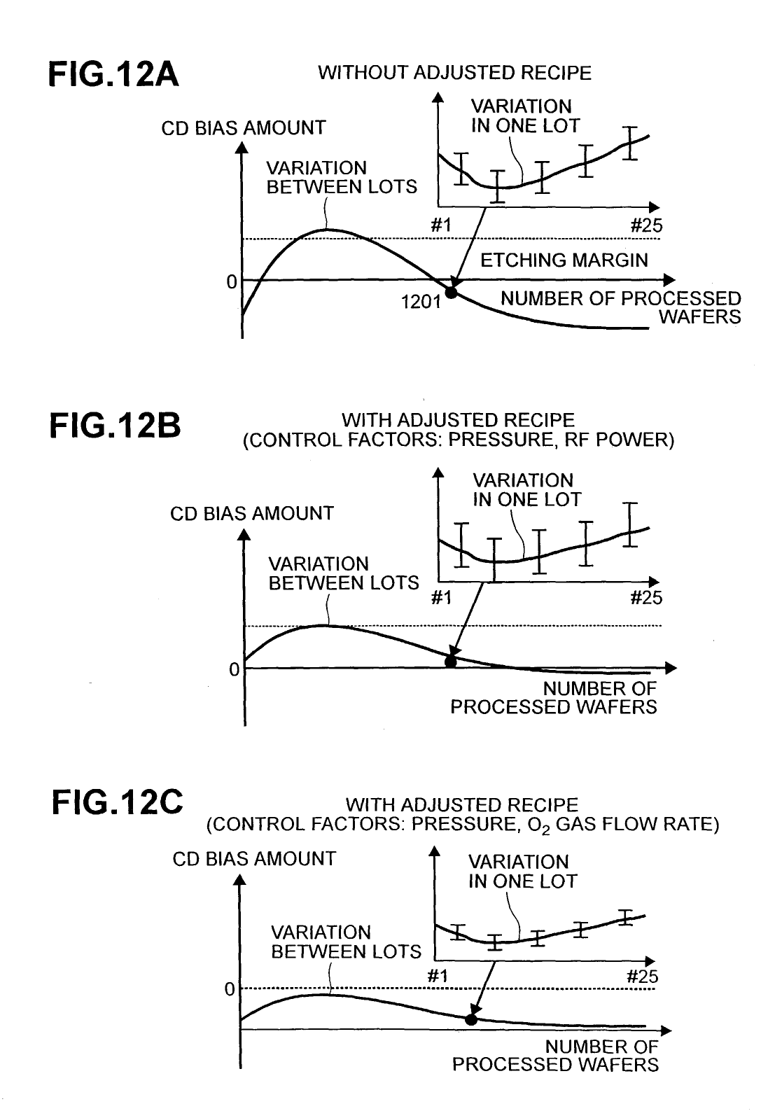

FIGS. 12A to 12C are graphs showing a comparison between the effect of the apparatus stabilization of the present invention and that of the conventional technique. The CD bias amount is shown along the vertical axis, and the CD value is increased with an upward increase in the CD bias amount in each of the graphs. It is desired that the CD bias amount be maintained at a slightly positive value from the standpoint of production management. However, the states of the plasma and the etching chemistry are changed by the deposition of the reactant film on the inner walls of the etching reactor, which tends to cause a long range change in the etching, although the degree of each of the changes in the states is very small. Such a long range change is referred to as “variation between lots” in FIGS. 12A to 12C. The variation between lots is especially large during a period, which begins after leaning of the etching reactor by opening the reactor to the air for the removal of deposits and extends to a time when stabilization of the state of the inner walls of the reactor has been achieved. Also, a short range change (variation in one lot) is caused in one lot due to the deposition of the reactant film or a temperature change of the inner walls. Further, an irregularity exists on one wafer due to the photolithography and the etching.

FIGS. 12A to 12C show the variation between lots under three different recipes, each of which includes a curve showing the variation in one lot on the dot plotted on the graph and the irregularity on one wafer in the case of extracting 5 wafers from the lot. Here, one lot consists of 25 wafers. FIG. 12A shows the variations in the CD bias amount between a lot and another lot and in one lot, as well as the irregularity on one wafer in a conventional etching. The degree of each of the variations is represented by the width extending in the vertical direction.

Conventionally, these variations and the irregularity have been maintained within the acceptable range of the device processing by improvements on the hardware-side, such as temperature control of the inner wall or by removing, such as by cleaning, the deposits at an appropriate interval (e.g., for every lot or wafer) to thereby stabilize the state of the etching reactor. However, with the progress toward microfabrication of the device, the acceptable range has become so narrow that the conventional technique no longer achieves the required stability of the reactor.

FIG. 12B shows results of a model-based feedback control, using the pressure and the RF power as control factors, and a feed-forward control, wherein the etching amount is optimized with respect to the resist CD value. In comparison with the case where the recipe is not adjusted, the irregularity on one wafer is undesirably increased, although both the variations between a lot and another lot, and within one lot, are suppressed.

FIG. 12C shows results of a model-based feedback control, using the pressure and the O₂ gas flow rate as control factors, and a feed-forward control, wherein the etching amount is optimized with respect to the resist CD value. In comparison with the case where the RF power is used as one of the control factors, not only the variations between a lot and another lot, and within one lot, but also the irregularity on one wafer, are suppressed, so that the etching is performed within the allowable range of variation.

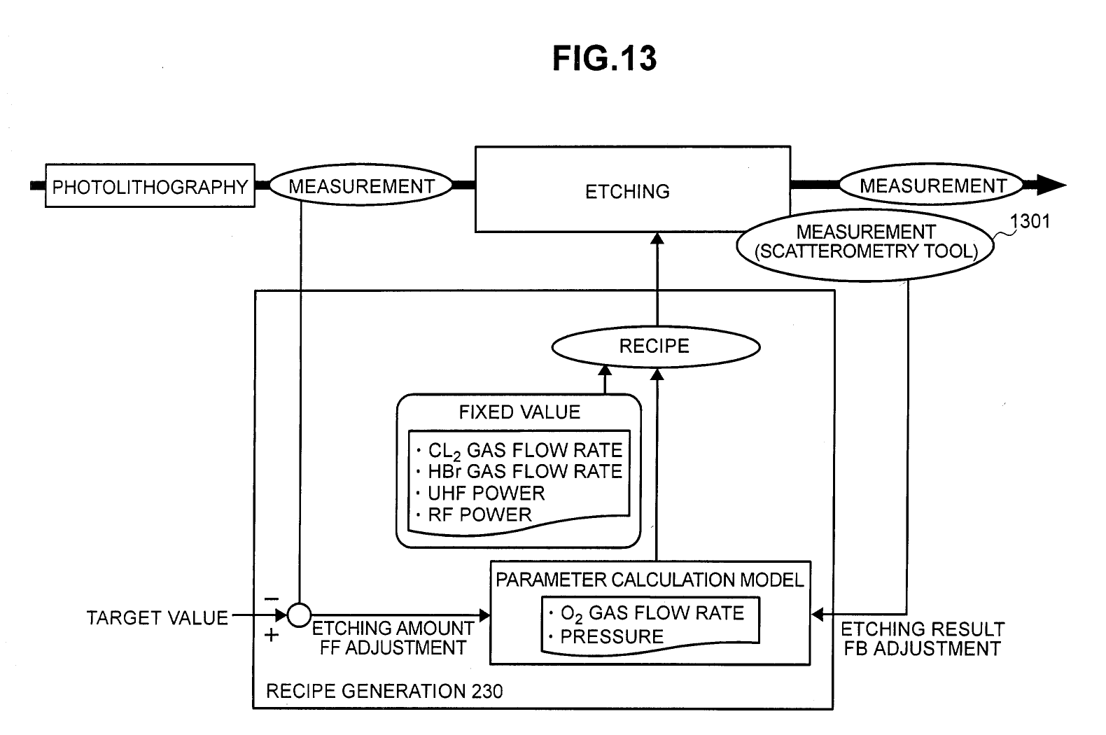

A second embodiment of the present invention will be described with reference to FIG. 13.

FIG. 13 is a diagram showing the second embodiment. Descriptions of those parts which are also shown in FIG. 2 will be omitted. In the present embodiment, scatterometry (a measurement technique) 1301 is employed in place of the In-Situ sensor 242 of FIG. 2. In the use of scatterometry 1301, a plurality of lattice-like marks on a wafer are irradiated with light, having a wavelength or an incident angle set as a parameter, to measure reflectivity. The thus-measured reflectivity is compared with a characteristic library, which has been prepared by theoretical calculations, to find a library wavelength associated with the reflectivity and to adjust the shape parameters, thereby estimating a shape and dimensions of the wafer which has been provided with the plurality of lattice-like marks.

A scatterometry tool for performing the scatterometry 1301 is incorporated in an etching apparatus as a measurement tool for monitoring the amount of processing (integrated metrology), so as to measure the dimensions and the shape of a wafer immediately after an etching is carried out in the etching apparatus for obtaining the estimation. The parameter calculation model is adjusted based on the estimation result in the same manner as described with reference to FIG. 2.

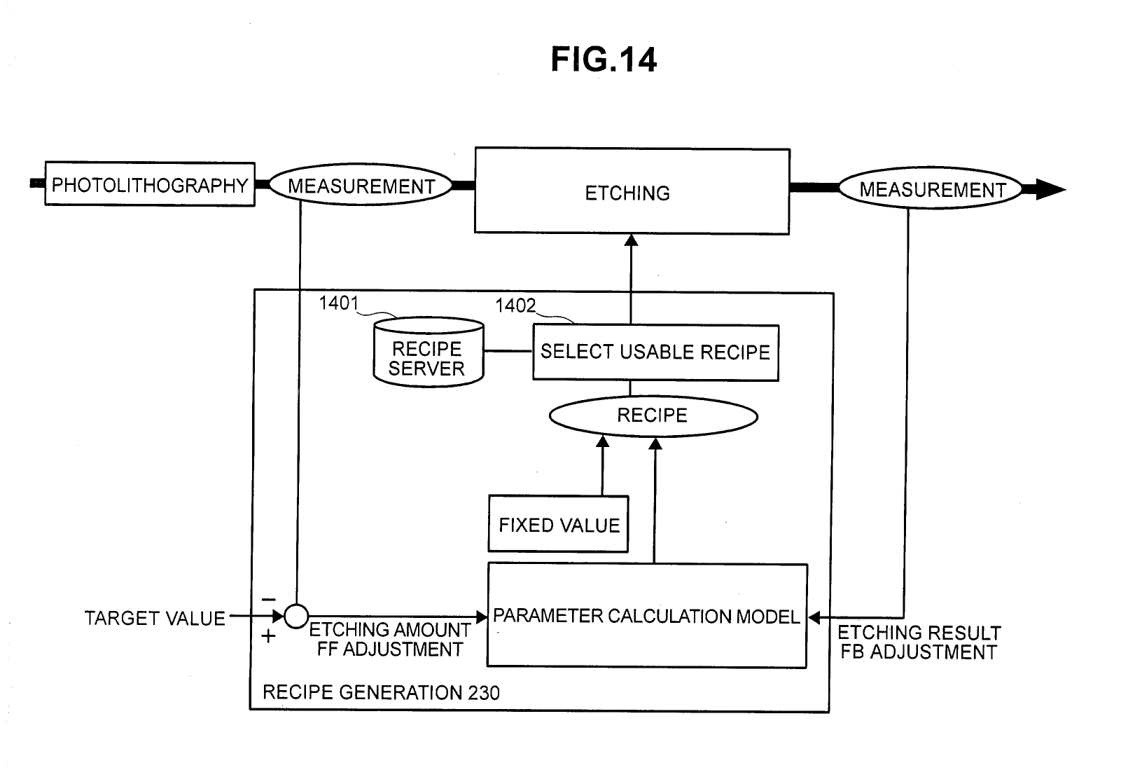

FIG. 14 is a diagram showing a third embodiment of the present invention. Descriptions of those parts which are also shown in FIG. 2 will be omitted. The etching result estimation model shown in FIG. 2 is not used in the present embodiment. Due to the absence of the etching result estimation model, the loop speed of the feedback is decreased, but a feedback using measurement values of an actual etching becomes possible. Therefore, the parameter calculation model will be adjusted much more accurately.

In the present embodiment, a function 1402 for selecting a usable recipe among generated recipes, with reference to recipes having past records, is added. Thus, it is possible to generate a recipe, which is to be outputted from the parameter calculation model, in accordance with past records.

According to the embodiments described above, feedback control and feed-forward control are performed based on outputs from a sensor for monitoring the processing amount or the measurement results of the etching result measurement tool. Therefore, it is possible to suppress the variations between one lot and another lot, and within one lot, as well as the irregularity on one wafer which occurs with the lapse of time, thereby realizing accurate device processing.

The invention also enables the achievement of target pattern dimensions by finely controlling a plurality of recipes, wafer by wafer, without causing deterioration in the uniformity in final pattern dimensions. Further, the invention attains the effect of improving the productivity through improvement of the apparatus operation rate, which is achieved by largely decreasing the frequency of maintenance, such as the cleaning of the apparatus, etc.

Any one of the foregoing embodiments enables the provision of a dry etching apparatus and a dry etching method that is capable of finely controlling the recipes, wafer by wafer, to achieve desired pattern dimensions. Further, any one of the foregoing embodiments enables the provision of a dry etching apparatus and a dry etching method, which produce less variation in the final pattern dimensions.

What is claimed is:

1. An etching apparatus, wherein, when a semiconductor substrate prepared using polysilicon is etched, at least one of values of an oxygen gas flow rate and a pressure or both values are changed to control an etching amount, the oxygen gas flow rate and the pressure being used as parameters for controlling the etching.

2. An etching apparatus for subjecting a substrate placed in a vacuum chamber to etching, comprising:
a parameter calculation means for calculating, based on an etching estimation result, such a value as to provide a target etching amount for at least one of values of an oxygen gas flow rate and a pressure or both values, which are used as parameters for controlling etching,
wherein a subsequent etching is performed based on the calculation result provided by the parameter calculation means.

3. An etching apparatus for subjecting a substrate placed in a vacuum chamber to etching based on a recipe consisting of a plurality of parameters, comprising:
a control means for obtaining values of the parameters through a calculation to generate the recipe associated therewith for etching control,
wherein the control unit sets each of a chlorine gas flow rate, a hydrogen bromide gas flow rate, an ultra high frequency power, a coil current, a temperature, an etching time, and a gap between electrodes included in the plurality of parameters to a fixed value to control the etching.

4. An etching apparatus for subjecting a substrate placed in a vacuum chamber to etching based on a recipe consisting of a plurality of parameters, comprising:
a sensor for monitoring a state of the etching in the vacuum chamber;
an etching result estimation means for estimating an etching result based on a monitor output from the sensor and a predetermined etching result estimator; and
a recipe generation means for generating the recipe that will achieve a target etching result based on an estimation result provided by the etching result estimation means;
wherein the recipe generation means has a parameter calculation model used for calculating the parameters from the target etching result and generates the recipe by calculating a set value for at least one of values of an oxygen gas flow rate and a pressure or both values which are included in the parameters by the use of the parameter calculation model while by setting each of the rest of the parameters to a fixed value, and then a subsequent etching is performed based on the thus-generated recipe.

5. An etching method, wherein, when a semiconductor substrate prepared using polysilicon is etched, at least one of values of an oxygen gas flow rate and a pressure or both values are changed to control an etching amount, the oxygen gas flow rate and the pressure being used as parameters for controlling the etching.

6. An etching method for subjecting a substrate placed in a vacuum chamber to etching, comprising:
calculating, based on an etching estimation result, such a value as to provide a target etching amount for at least one of values of an oxygen gas flow rate and a pressure or both values, which are used as parameters for controlling etching; and
performing a subsequent etching based on the calculation result provided for the parameter.

7. An etching method for performing an etching based on a recipe consisting of a plurality of parameters, comprising:
setting each of a chlorine gas flow rate, a hydrogen bromide gas flow rate, an ultra high frequency power, a coil current, a temperature, an etching time, and a gap between electrodes included in the plurality of parameters to a fixed value to control the etching.

8. An etching method for performing an etching based on a recipe consisting of a plurality of parameters, comprising:
monitoring a state of the etching;
estimating from the etching state an etching result using a predetermined etching result estimator; and
generating the recipe by calculating, based on the estimated etching result, a parameter set value that will achieve a target etching result for at least one of values of an oxygen gas flow rate and a pressure or both values which are included in the parameters while by setting each of the rest of the parameters to a fixed value; and
performing a subsequent etching based on the thus-generated recipe.
